(19) United States
(12) Patent Application Publication
(10) Pub. No.: US 2016/0268931 A1
(43) Pub. Date: Sep. 15, 2016

(54) SYSTEM FOR CONVERTING MECHANICAL AND/OR THERMAL ENERGY INTO ELECTRICAL POWER

(71) Applicant: COMMISSARIAT A L'ENERGIE ATOMIQUE ET AUX ENERGIES ALTERNATIVES, Paris (FR)

(72) Inventors: Abdelkader Aliane, Grenoble (FR); Poncelet Olivier, Grenoble (FR)

(73) Assignee: Commissariat à l'Énergie Atomique et aux Énergies Alternatives, Paris (FR)

(21) Appl. No.: 15/033,894

(22) PCT Filed: Oct. 23, 2014
(86) PCT No.: PCT/FR2014/052709

§ 371 Date: May 2, 2016

(30) Foreign Application Priority Data
Nov. 15, 2013 (FR) 1361163

(51) Int. Cl. H02N 2/18; H02N 2/00; H01L 41/193; F03G 7/06; H01L 41/08

(52) U.S. Cl. CPC H02N 2/18; F03G 7/06; H01L 41/0805; H01L 41/193; H02N 2/22

(57) ABSTRACT

A system for converting energy, comprising a first device comprising a deformable enclosure containing thermo-reactive molecules suitable for deforming the enclosure when their temperature exceeds a threshold temperature, and a second pyroelectric and/or piezoelectric device making contact with the enclosure.

### CROSS-REFERENCE TO THE RELATED APPLICATIONS

This application is the national phase of International Application No. PCT/FR2014/052709, filed on Oct. 23, 2014, which claims the priority benefit of French patent application FR 13/61163, filed on Nov. 15, 2013, which applications are hereby incorporated by reference to the maximum extent allowable by law.

### BACKGROUND

The present application relates to a system enabling to convert thermal and/or mechanical energy into electrical energy and to a method of manufacturing such a system.

### DISCUSSION OF THE RELATED ART

Systems for converting thermal/mechanical energy into electrical energy may in particular be used to form pressure sensors, switches, or energy recovery systems.

It is known to form energy conversion systems by using piezoelectric and/or pyroelectric films. However, the piezoelectric and/or pyroelectric action of films known to date may be insufficient to form a system of conversion of thermal and/or mechanical energy into electrical energy which has a sufficient sensitivity.

Further, when the energy conversion system is used to form a switch, particularly a switch manually actuated by a user, it may be desirable, when the user actuates the switch, for the switch to exert in return a mechanical force on the user, for example, the application of an overpressure, particularly so that the user can be sure of having properly actuated the switch. It is then necessary to provide additional means for providing this mechanical reaction.

### SUMMARY

An embodiment aims at overcoming all or part of the disadvantages of known systems of conversion of thermal/mechanical energy into electrical energy.

Another embodiment aims at enabling to use a pyroelectric and/or piezoelectric film to form the energy conversion system.

Another embodiment aims, in the case of a use of the energy conversion system to form a pressure sensor or a switch, at increasing the sensitivity of the energy conversion system.

Another embodiment aims, in the case of a use of the energy conversion system to form a switch, at providing a mechanical reaction to the user when he/she actuates the switch.

Thus, an embodiment provides an energy conversion system comprising:

a first device comprising a deformable enclosure containing heat-sensitive molecules capable of deforming the enclosure when the temperature exceeds a threshold temperature; and

a second pyroelectric and/or piezoelectric device in contact with the enclosure.

According to an embodiment, the second device comprises a film comprising polyvinylidene fluoride and/or at least one copolymer of polyvinylidene fluoride.

According to an embodiment, the film comprises a polymer selected from the group comprising polyvinylidene fluoride, poly(vinylidene fluoride-trifluoroethylene), poly(vinylidene fluoride-tetrafluoroethylene) and a mixture of at least two of these polymers.

According to an embodiment, the heat-sensitive molecules are molecules having a characteristic transition temperature and which are adapted, when they are submitted to a temperature variation from a first temperature lower than the characteristic transition temperature to a second temperature higher than the characteristic transition temperature, of passing from a first state where the enclosure occupies a first volume to a second state where the enclosure occupies a second volume different from the first volume, and capable, when they are submitted to a temperature variation from the second temperature to the first temperature, of passing from the second state to the first state.

According to an embodiment, the heat-sensitive molecules are selected from the group comprising poly (N-isopropyl acrylamide), polyvinylcaprolactame, hydroxypropylcellulose, polyoxazoline, polyvinylmethylether, polyethylene glycol, poly-3-dimethyl(methacryloyloxyethyl) ammonium propane sulfonate, poly(propyl sulfonate dimethyl ammonium ethyl methacrylate), and the mixture of at least two of these polymers.

Another embodiment provides a method of manufacturing an energy conversion system, comprising the steps of:

forming a first device comprising a deformable enclosure containing heat-sensitive molecules capable of deforming the enclosure when the temperature exceeds a threshold temperature; and

forming a second pyroelectric and/or piezoelectric device, the second device being in contact with the enclosure.

According to an embodiment, the second pyroelectric and/or piezoelectric device comprises a film comprising polyvinylidene fluoride and/or at least one copolymer of polyvinylidene fluoride, the method comprising the steps of:

forming a portion of a layer of a solution comprising a solvent and a compound comprising polyvinylidene fluoride and/or said at least one copolymer of polyvinylidene fluoride; and

irradiating, at least partially, the portion with pulses of at least one ultraviolet radiation.

According to an embodiment, the duration of each pulse is in the range from 500 μs to 2 ms.

According to an embodiment, the fluence of the ultraviolet radiation is in the range from 10 J/cm² to 25 J/cm².

According to an embodiment, the solvent has an evaporation temperature in the range from 110° C. to 140° C.

### BRIEF DESCRIPTION OF THE DRAWINGS

The foregoing and other features and advantages will be discussed in detail in the following non-limiting description of specific embodiments in connection with the accompanying drawings, among which:

FIG. 1 is a partial simplified cross-section view of an embodiment of a system for converting mechanical and/or thermal energy into electrical energy;

FIG. 2 is a cross-section view similar to FIG. 1, in the case of a use of the embodiment of the energy conversion system shown in FIG. 1 as a switch; and

FIGS. 3A to 3H are partial simplified cross-section views of the structures obtained at successive steps of another embodiment of a method of manufacturing the energy conversion system of FIGS. 1 and 2.

### DETAILED DESCRIPTION

For clarity, the same elements have been designated with the same reference numerals in the various drawings and, further, as usual in the representation of electronic circuits, the various drawings are not to scale. Further, only those elements which are useful to the understanding of the present description have been shown and will be described. In particular, the circuit for processing the electric signals supplied by the energy conversion system is well known by those skilled in the art according to the envisaged application and is not described in detail hereafter. In the following description, unless otherwise indicated, terms “substantially”, “approximately”, and “in the order of” mean “to within 10%”. In the following description, expression element “based on poly-vinylidene fluoride (PVDF)” means an element comprising at least 70% wt. of the PVDF polymer and/or of at least one copolymer of PVDF.

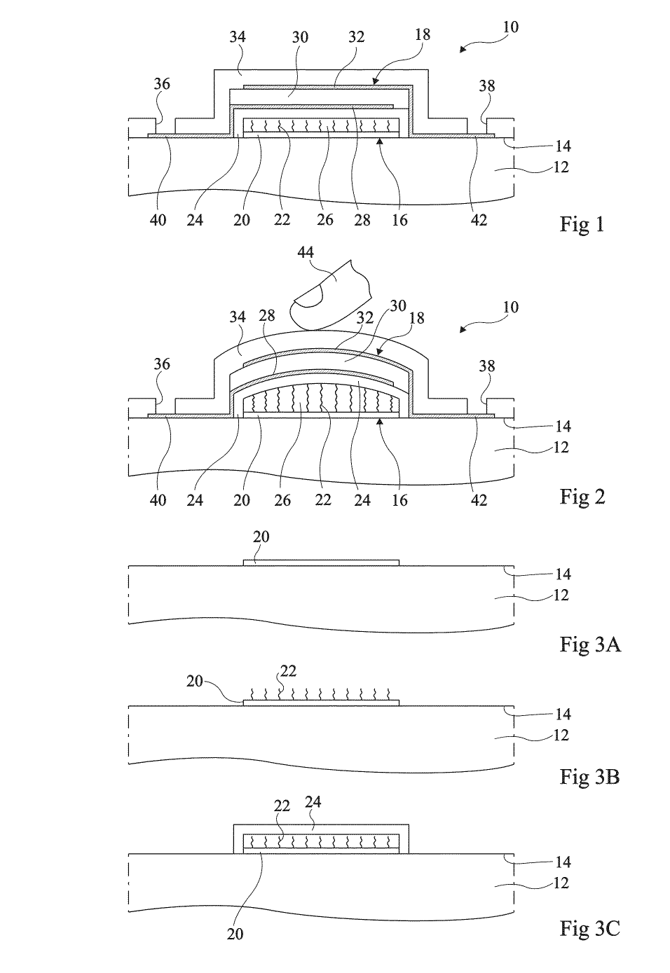

FIG. 1 shows an embodiment of an energy conversion system 10.

System 10 comprises a substrate 12 having an upper surface 14. Substrate 12 may be made of an insulating or semiconductor material. As an example, substrate 12 is made of glass, of silicon, or of a plastic material. Substrate 12 may be made of a polymer, for example, polyimide, polyethylene naphthalate (PEN), or polyethylene terephthalate (PET). As an example, the thickness of substrate 12 is in the range from 25 μm to 200 μm. Substrate 12 may be flexible.

System 10 comprises a device 16 which may be actuated with temperature, called heat-actuated device hereafter, and a piezoelectric and/or pyroelectric device 18. In the present embodiment, heat-actuated device 16 is interposed between substrate 12 and piezoelectric and/or pyroelectric device 18. However, as a variation, piezoelectric and/or pyroelectric device 18 may be interposed between heat-actuated device 16 and substrate 12.

Heat-actuated device 16 comprises a bonding layer 20 laid on surface 14 and having molecules 22 changing state according to temperature, called heat-sensitive molecules hereafter, bonded thereto. The nature of bonding layer 20 depends on the nature of heat-sensitive molecules 22. The thickness of bonding layer 20 may be in the range from 10 nm to 100 nm, for example, approximately 30 nm. As a variation, layer 20 may be a metal layer or a non-metallic layer, for example, made of fullerene or of polystyrene.

Term heat-sensitive molecule means a polymer molecule which exhibits a significant and discontinuous change in at least one physical property according to temperature. According to an embodiment, heat-sensitive molecules 22 have a characteristic transition temperature and are in a first state, that is, with a physical property at a first level, when the temperature is lower than the characteristic transition temperature and are in a second state, that is, with a physical property at a second level, when the temperature is higher than the characteristic transition temperature. This change is preferably reversible so that the molecules pass from the first state to the second state when the temperature rises above the characteristic transition temperature and passes from the second state to the first state when the temperature decreases below the characteristic transition temperature.

According to an embodiment, the considered property is the three-dimensional conformation of the molecule. According to another embodiment, the considered property is the solubility of the molecule in a solvent. According to an embodiment, the considered property is the hydrophobicity of the molecule.

According to an embodiment, in the first state, heat-sensitive molecules 22 may have a given affinity for water, while in the second state, heat-sensitive molecules 22 may have a reverse affinity for water. For example, in the first state, heat-sensitive molecules 22 may be hydrophobic (conversely, hydrophilic) while in the second state, heat-sensitive molecules 22 may be hydrophilic (conversely, hydrophobic). More generally, heat-sensitive molecules 22 may be such that they are capable of passing from a solvophobic character (conversely, solvophilic) to a solvophilic (conversely, solvophobic) character due to a temperature variation.

Advantageously, heat-sensitive molecules 22 may be selected from one or a plurality of the following polymers: poly(N-isopropylacrylamide) (polyNIPAM), polyvinylcaprolactame, hydroxypropylcellulose, polyoxazoline, polyvinylmethylether, polyethyleneglycol, poly-3-dimethyl(methacryloyloxyethyl) ammonium propane sulfonate (PDMAPS), and poly(propyl sulfonate dimethyl ammonium ethylmethacrylate).

The characteristic transition temperatures of these materials are the following:
polyNIPAM: between 30 and 37° C.;
polyvinylcaprolactame: 37° C.;
hydroxypropylcellulose: between 40 and 56° C.;
polyoxazoline: 70° C.;
polyvinylmethylether: 45° C.;
polyethyleneglycol: between 100 and 130° C.;
PDMAPS: between 32 and 35° C.;
poly(propyl sulfonate dimethyl ammonium ethyl methacrylate): 30° C.

In the present embodiment, for an application where system 10 is used as a mechanical switch actuated by a user, the characteristic transition temperature of heat-sensitive molecules 22 is preferably in the range from 30° C. to 37° C.

For an application as a switch actuated by an operator's finger, heat-sensitive molecule 22 is preferably PDMAPS having a characteristic transition temperature in the range from 32° C. to 35° C. and which passes from a hydrophobic state to a hydrophilic state when the temperature exceeds the characteristic transition temperature.

The material comprising the PDMAPS molecules may appear in the form of an aqueous gel which occupies a first volume when the temperature is below the characteristic transition temperature and a second volume, larger than the first volume, when the temperature is above the characteristic transition temperature.

According to an embodiment, heat-sensitive molecules 22 may be formed of a plurality of types of polymers capable of being activated by temperature, in particular with different respective characteristic transition temperatures.

It is possible to modify the characteristic transition temperature of the heat-sensitive polymer by adding a salt or by adding an appropriate surface-active agent or solvent to the polymer. Similarly, a modification of the characteristic transition temperature for a family of heat-sensitive polymers may be performed by forming of a copolymer, the copolymer supporting as desired a filler or an amphiphilic group.

Device 16 comprises a cap 24 covering heat-sensitive molecules 22 and which defines, with substrate 12, an enclosure 26 containing heat-sensitive molecules 22. Cap 24 is capable of being deformed on application of external mechanical stress. To achieve this, as an example, the thickness of cap 24 is in the range from 1 μm to 2 μm, to obtain a flexible membrane.

Preferably, cap 24 is made of a material which enables to have a good moisture input in enclosure 26. As an example, to confine water or humidity in enclosure 26, one may provide on the internal walls of enclosure 16 one or a plurality of areas having a good affinity for water such as, for example, polyimide (PI) or polydimethylsiloxane (PDMS). As an example, cap 24 is made of a material selected from the group comprising polyimide, poly(methyl methacrylate) (PMMA), poly(vinylcrotonate), and PET. Cap 24 may comprise openings for giving way to moisture.

Pyroelectric/piezoelectric device 18 comprises:

a first electrode 28 which extends over a portion of cap 24 and over a portion of surface 14;

a pyroelectric and/or piezoelectric film 30 covering a portion of electrode 28; and

a second electrode 32 which extends on film 30 and on a portion of surface 14.

First electrode 28 is preferably made of a material reflecting ultraviolet radiation, for example, over a wavelength range between 200 nm and 400 nm. It may be a metal layer. As an example, the material forming first electrode 28 is selected from the group comprising silver (Ag), aluminum (Al), gold (Au), or a mixture or an alloy of two or more than two of these metals.

Film 30 comprises a pyroelectric and/or piezoelectric material. Preferably, pyroelectric and/or piezoelectric film 30 is arranged to have a pyroelectric and/or piezoelectric activity along a direction perpendicular to surface 14. According to an embodiment, film 30 is made of a polymer material.

According to an embodiment, film 30 is based on PVDF. It may comprise the PVDF polymer alone, a single copolymer of PVDF, a mixture of two or more than two copolymers of PVDF, a mixture of the PVDF polymer and of at least one copolymer of PVDF. Preferably, the PVDF copolymer is poly(vinylidene fluoride-trifluoroethylene) (P(VDF-TrFe)) or poly(vinylidene fluoride-tetrafluoroethylene), particularly P(VDFx-TrFe100-x) where x is a real number in the range from 60 to 80. Film 30 may further comprise fillers. The fillers may correspond to ceramic particles, for example, to particles of barium titanate (BaPiO3) or particles of lead zirconate titanate (LZT). The concentration by weight of fillers in film 30 may vary from 5% to 25% wt. The thickness of film 30 is in the range from 200 nm to 4 μm. The PVDF polymer or the PVDF copolymer of film 30 is a semicrystalline polymer comprising, in particular, a β crystalline phase which may have pyroelectric and/or piezoelectric properties.

Second electrode 32 is, for example, made of a metallic material selected from the group comprising silver, copper, or a mixture or an alloy of at least two of these materials.

A protection layer 34, for example, made of an insulating material, covers the entire structure. Openings 36, 38 may be provided in protection layer 34 to expose a portion 40 of first electrode 28 and a portion 42 of second electrode 32. Protection layer 34 is made of a dielectric material. The dielectric material may be selected from the group comprising polytetrafluoroethylene (Teflon), a fluorinated polymer of the type of the polymer commercialized by Bellex under trade name Cytop, a polystyrene, and a polyimide.

FIG. 2 illustrates an example of illustration of system 10 as a switch actuated by finger 44 of an operator. For such an application, heat-sensitive molecules 22 are preferably made of PDMAPS having a characteristic transition temperature in the range from 32° C. to 35° C. PDMAPS passes from a hydrophobic state to a hydrophilic state when the temperature exceeds the characteristic transition temperature. The material forming bonding layer 20 may be gold.

The PDMAPS molecules may be arranged in enclosure 26 in the form of an aqueous gel which occupies a first volume when the temperature is below the characteristic transition temperature and which occupies a second volume, larger than the first volume, when the temperature is above the characteristic transition temperature.

When a user presses finger 44 on the portion of protection layer 34 covering pyroelectric/piezoelectric film 30, a pressure is exerted on film 30, which results in the occurrence of a voltage between electrodes 28, 32.

In the case where film 30 has both piezoelectric and pyroelectric properties, which may be the case for a PVDF-based film, the presence of finger 44 causes a rise in the temperature of film 30, which increases the voltage between electrodes 28, 32.

Further, the presence of finger 44 causes a rise in the temperature in enclosure 26 beyond the characteristic transition temperature of heat-sensitive molecules 22. This causes an increase in the volume occupied by the heat-sensitive molecules 22 and a deformation of cap 24. As an example in FIG. 2, cap 24 has been shown with an outward-bulged shape due to the increase in the volume of enclosure 26. However, the deformed shape of cap 24 may be different from the shape shown in FIG. 2. The thin thickness of cap 24 advantageously provides a significant deformation of cap 24 as the volume of enclosure 26 changes.

The deformation of cap 24 causes an additional deformation of film 30, in addition to the pressure exerted by finger 44. Thereby, the voltage between electrodes 28, 32 is greater than that which would be obtained by only applying finger 44. The switch sensitivity is thus improved.

Further, when he/she actuates system 10 by touching it with finger 44, the abrupt increase in the volume of enclosure 26 is sensed by the user. A mechanical return function is thus obtained without using additional means.

According to another example of use, there is no application of pressure on piezoelectric film 30 by an external member. The deformation of piezoelectric film 30, and thus the occurrence of a voltage between electrodes 28 and 32, is only obtained by the change of volume of enclosure 26 when the temperature in enclosure 26 exceeds the characteristic transition temperature of heat-sensitive molecules 22. As an example, system 10 shown in FIG. 1 may be used as a thermally-actuated switch. In this case, the characteristic transition temperature of heat-sensitive molecules 22 is selected according to the temperature threshold beyond which an actuation of the switch is desired. Indeed, when the temperature in enclosure 26 exceeds the threshold temperature, the volume of enclosure 26 increases, which causes a deformation of piezoelectric film 30 and thus the occurrence of a voltage between electrodes 28 and 32. According to another example of use, the temperature modification in enclosure 26 may be obtained by the application of a local heat source at the level of enclosure 26, for example, with a laser. A system for converting thermal energy into electrical energy is then obtained.

The present energy conversion system 10 may also be implemented as a thermal or electrical energy recovery system.

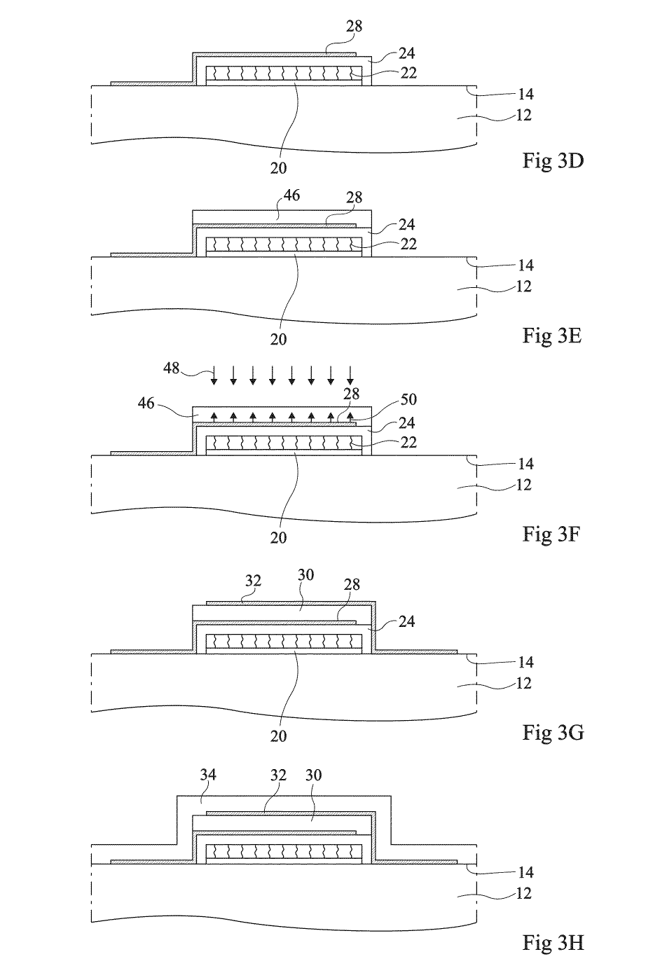

FIGS. 3A to 3H illustrate an embodiment of a method of manufacturing energy conversion system 10 shown in FIG. 1.

FIG. 3A shows the structure obtained after having formed bonding layer 20 on substrate 12. The bonding layer may be deposited by physical vapor deposition (PVD).

FIG. 3B shows the structure obtained after having grafted heat-sensitive molecules 22 to bonding layer 20. The grafting method may be implemented as described in A. Housni and Y. Zhao's publication entitled “Gold Nanoparticles Functionalized with Block Copolymers Displaying Either LCST ou UCST Thermosensitivity in Aqueous Solution”, Langmuir, 2010, 26 (15), pp. 12933-12939. Other examples of grafting methods are described in French application FR13/54701 which is herein incorporated by reference.

FIG. 3C shows the structure obtained after having formed cap 24. Cap 24 may be formed by printing techniques, for example, by inkjet printing or by sputtering. An anneal step enabling to evaporate the solvents having the polymers dissolved therein may be provided to form a film. The anneal step may be formed by irradiation by a succession of ultraviolet (UV) radiation pulses, or UV flashes. UV radiation means a radiation having its wavelengths at least partly in the range from 200 nm to 400 nm. According to an embodiment, the duration of a UV pulse is in the range from 500 μs to 2 ms. The duration between two successive UV pulses may be in the range from 1 to 5 seconds. The fluence of the UV radiation may be in the range from 10 J/cm2 to 21 J/cm2.

FIG. 3D is a partial simplified cross-section view of the structure obtained after having formed first electrode 28 on cap 24 and on substrate 12. The deposition of first electrode 28 may be formed by PVD or by printing techniques, particularly by silk screening or by inkjet printing.

FIG. 3E shows the structure obtained after having formed a liquid portion 46, possibly viscous, which extends on the portion of first electrode 28 covering cap 24 and, possibly, directly on a portion of cap 24. Liquid portion 46 comprises a solvent and a PVDF-based compound dissolved in the solvent. The thickness of portion 46 is in the range from 200 nm to 4 μm.

The PVDF-based compound may comprise the PVDF polymer alone, a single copolymer of PVDF, a mixture of two or more than two copolymers of PVDF or a mixture of the PVDF polymer and of at least one copolymer of PVDF. Preferably, the PVDF copolymer is poly(vinylidene fluoride-trifluoroethylene) (P(VDF-TrFe)) or poly(vinylidene fluoride-tetrafluoroethylene), particularly P(VDFx-TrFe100-x) where x is a real number in the range from 60 to 80.

The PVDF-based compound may further comprise fillers. The fillers may correspond to ceramic particles, for example, to particles of barium titanate (BaPiO3) or particles of lead zirconate titanate (LZT). The concentration by weight of fillers in the PVDF-based compound may vary from 5% to 25% wt.

Preferably, the solvent is a polar solvent. This advantageously enables to improve the dissolution of the PVDF-based polymer. Preferably, the solvent is capable of absorbing, at least partially, the UV radiation, for example, over a wavelength range between 200 nm and 400 nm. According to an embodiment, the evaporation temperature of the solvent is in the range from 110° C. to 140° C., preferably from 110° C. to 130° C., more preferably from 120° C. to 130° C. The solvent may be selected from the group comprising cyclopentanone, dimethylsulphoxide (DMSO), dimethylformamide (DMF), dimethylacetamide (DMAc), or N-methyl-E-pyrrolidone (NMP). Preferably, the solvent is cyclopentanone.

Liquid portion 46 comprises from 1% to 30%, preferably from 1% to 20%, by weight of the PVDF-based compound, and from 70% to 99%, preferably from 80% to 99%, by weight of the solvent. Advantageously, the concentration by weight of the solvent is selected to adjust the viscosity of the obtained solution to enable to implement printing techniques. The method of deposition portion 46 may correspond to a so-called additional method, for example, by direct printing of portion 46 at the desired locations, for example, by inkjet printing, photogravure, silk-screening, flexography, spray coating, or drop casting. The method of depositing portion 46 may correspond to a so-called subtractive method, where portion 46 is deposited all over the structure and where the non-used portions are then removed, for example, by photolithography or laser ablation. According to the considered material, the deposition over the entire structure may be performed, for example, by liquid deposition, by cathode sputtering, or by evaporation. Methods such as spin coating, spray coating, heliography, slot-die coating, blade coating, flexography, or silk-screening, may in particular be used.

FIG. 3F illustrates a step of irradiating at least a portion of liquid portion 46, which causes the forming, in the portion, of a PVDF-based film having the desired pyroelectric and/or piezoelectric properties. The UV irradiation is schematically shown in FIG. 3F by arrows 48. The irradiation is carried out by a succession of UV radiation pulses. According to an embodiment, the duration of a UV pulse is in the range from 500 μs to 2 ms. The duration between two successive UV pulses may be in the range from 1 to 5 seconds. The fluence of the (UV) radiation may be in the range from 10 J/cm2 to 25 J/cm2. The number of UV pulses particularly depends on the thickness of portion 46. As an example, for a 200-nm thickness of portion 46, the number of UV pulses may be in the range from 1 to 2 with a fluence between 10 J/cm2 and 15 J/cm2 and for a thickness of portion 46 in the order of 4 μm, the number of UV pulses may be in the range from 2 to 6 with a fluence between 17 J/cm2 and 21 J/cm2.

Advantageously, during the irradiation of portion 46, first electrode 28 reflects a portion of the UV radiation having crossed portion 46. This enables to improve the quantity of UV radiation received by portion 46. The reflection of UV rays is schematically shown in FIG. 3F by arrows 50.

Advantageously, the solvent of portion 46 at least partly absorbs the UV radiation. This enables to improve the UV-based heating of the compound and favors the forming of the β crystalline phase. The evaporation temperature of the solvent is advantageously higher than 110° C. to avoid too fast an evaporation of the solvent before the forming of the β crystalline phase, which occurs between 120° C. and 130° C.

Preferably, the irradiation step causes an evaporation of more than 50%, preferably more than 80%, by weight of the solvent of portion 46. The irradiation step causes the forming of pyroelectric and/or piezoelectric film 30.

The inventors have shown that the diffraction diagram of film 30 comprises two peaks representative of two β crystalline phases having different directions. The inventors have further shown that film 30 based on PVDF has a pyroelectric or piezoelectric activity improved over that of a PVDF-based film which would be heated by a heating plate for a duration varying from several minutes to several hours.

FIG. 3G shows the structure obtained after having deposited second electrode 32 on film 30 and on a portion of substrate 14, and second electrode 32 does not come into contact with first electrode 28. Electrode 32 is for example made of a metallic material selected from the group comprising silver, copper, or a mixture or an alloy of at least two of these materials. According to the considered material, electrode 32 may be deposited by PVD or by printing techniques, for example, by inkjet or by silk screening. In this case, an anneal step may then be provided, for example, by irradiation of the ink deposited by UV pulses having a fluence between 15 J/cm2 and 25 J/cm2.

A subsequent step of application of an electric field to the structure may be provided. As an example, the electric field may vary between 20 and 80 V/μm and may be applied at a temperature in the range from 70 to 90° C. for from 5 to 10 minutes.

FIG. 3H shows the structure obtained after the forming of protection layer 34. According to the considered material, protection layer 34 may be deposited by chemical vapor deposition (CVD) or by printing techniques, for example, by inkjet printing or by silk screening. In this case, an anneal step may then be provided, for example, by irradiation of the ink deposited by UV pulses having a fluence between 10 J/cm2 and 21 J/cm2.

The fact of carrying out the steps of heating the materials forming cap 24 and pyroelectric and/or piezoelectric device 18 by UV irradiation advantageously enables to perform a local heating without deteriorating the heat-sensitive molecules.

Specific embodiments have been described. Various alterations, modifications, and improvements will readily occur to those skilled in the art.

1. An energy conversion system comprising:
a first device comprising a deformable enclosure containing heat-sensitive molecules capable of deforming the enclosure when the temperature exceeds a threshold temperature; and
a second pyroelectric and/or piezoelectric device in contact with the enclosure.

2. The system of claim 1, wherein the second device comprises a film comprising polyvinylidene fluoride and/or at least one copolymer of polyvinylidene fluoride.

3. The system of claim 2, wherein the film comprises a polymer selected from the group comprising polyvinylidene fluoride, poly(vinylidene fluoride-trifluoroethylene), poly(vinylidene fluoride-tetrafluoroethylene), and a mixture of at least two of these polymers.

4. The system of claim 1, wherein the heat-sensitive molecules are molecules having a characteristic transition temperature and which are adapted, when they are submitted to a temperature variation from a first temperature lower than the characteristic transition temperature to a second temperature higher than the characteristic transition temperature, of passing from a first state where the enclosure occupies a first volume to a second state where the enclosure occupies a second volume different from the first volume, and capable, when they are submitted to a temperature variation from the second temperature to the first temperature, of passing from the second state to the first state.

5. The system of claim 4, wherein the heat-sensitive molecules are selected from the group comprising poly (N-isopropyl acrylamide), polyvinylcaprolactame, hydroxypropyl-cellulose, polyoxazoline, polyvinylmethylether, polyethylene glycol, poly-3-dimethyl(methacryloyloxyethyl) ammonium propane sulfonate, poly(propyl sulfonate dimethyl ammonium ethyl methacrylate), and the mixture of at least two of these polymers.

6. A method of manufacturing an energy conversion system, comprising the steps of:
forming a first device comprising a deformable enclosure containing heat-sensitive molecules capable of deforming the enclosure when the temperature exceeds a threshold temperature; and
forming a second pyroelectric and/or piezoelectric device,
wherein the second device is in contact with the enclosure.

7. The method of claim 6, wherein the second pyroelectric and/or piezoelectric device comprises a film comprising polyvinylidene fluoride and/or at least one copolymer of polyvinylidene fluoride, the method comprising the steps of:
forming a portion of a solution comprising a solvent and a compound comprising polyvinylidene fluoride and/or said at least one copolymer of polyvinylidene fluoride; and
irradiating, at least partially, the portion with pulses of at least one ultraviolet radiation.

8. The method of claim 7, wherein the duration of each pulse is in the range from 500 μs to 2 ms.

9. The method of claim 7, wherein the fluence of the ultraviolet radiation is in the range from 10 J/cm² to 25 J/cm².

10. The method of claims 7, wherein the solvent has an evaporation temperature in the range from 110° C. to 140° C.
